(19) United States
(12) Patent Application Publication
(10) Pub. No.: US 2018/0366552 A1
(43) Pub. Date: Dec. 20, 2018

(54) SEMICONDUCTOR DEVICE

(71) Applicant: SAMSUNG ELECTRONICS CO., LTD., Suwon-si (KR)

(72) Inventors: Yongkuk JEONG, Yongin-si (KR); Joohyun PARK, Suwon-si (KR); Hyoseok LEE, Seoul (KR)

(21) Appl. No.: 15/869,642

(22) Filed: Jan. 12, 2018

(30) Foreign Application Priority Data
Jun. 19, 2017 (KR) 10-2017-0077320

(51) Int. Cl. H01L 29/423; H01L 27/088; H01L 21/8234; H01L 29/66

(52) U.S. Cl. CPC H01L 29/42364; H01L 27/0886; H01L 29/66545; H01L 21/823468; H01L 21/823431

(57) ABSTRACT

A semiconductor device includes a plurality of active patterns that protrude from a substrate. The semiconductor device further includes a gate structure. The gate structure is formed on the active patterns, and crosses over the active patterns. The gate structure includes a metal. The semiconductor structure further includes a capping structure formed on the gate structure, and a dielectric residue protruding from an upper surface of the gate structure. The dielectric residue extends into the capping structure, and includes a metal.

### CROSS-REFERENCE TO RELATED APPLICATION

This application claims priority under 35 USC § 119 to Korean Patent Application No. 10-2017-0077320, filed on Jun. 19, 2017, in the Korean Intellectual Property Office, the disclosure of which is incorporated by reference herein in its entirety.

### TECHNICAL FIELD

Example embodiments of the present inventive concept relate generally to a semiconductor device and methods of manufacturing the same. More particularly, example embodiments relate to a semiconductor device including a fin-type field effect transistor (finFET) and methods of manufacturing the same.

### DISCUSSION OF THE RELATED ART

Recently, a highly integrated semiconductor device including a finFET having good characteristics is needed. When a gate structure is formed, a metal residue may be generated at an upper surface of the gate structure. An electrical short may occur between the gate structure and a conductive pattern. As a result, the finFET may not function properly.

### SUMMARY

According to an exemplary embodiment of the present inventive concept, a semiconductor device includes a plurality of active patterns protruding from a surface of a substrate, and a gate structure on the active patters. The gate structure crosses over the active patterns and includes a first metal. The semiconductor device further includes a capping structure on the gate structure, and a dielectric residue. The dielectric residue protrudes from an upper surface of the gate structure, and extends into the capping structure. The dielectric residue includes a metal.

According to an exemplary embodiment of the present inventive concept, a semiconductor device includes a plurality of active patterns protruding from a surface of a substrate. The semiconductor device further includes an insulating interlayer covering sidewalls and upper surfaces of the active patterns. The insulating interlayer includes an opening. The opening extends in a direction crossing an extension direction of the active patterns. The semiconductor device further includes a gate structure in the opening. The gate structure includes a gate insulation layer and a gate electrode. The semiconductor device further includes a capping structure on the gate structure. The capping structure includes a capping layer and at least one surface treatment layer stacked on each other.

According to an exemplary embodiment of the present inventive concept, a semiconductor device includes a plurality of active patterns protruding from a surface of a substrate. The semiconductor device further includes an insulating interlayer covering sidewalls and upper surfaces of the active patterns. The insulating interlayer includes an opening extending in a direction crossing an extension direction of the active patterns. The semiconductor device further includes a gate structure in a lower portion of the opening. The gate structure includes a metal. The semiconductor device further includes a capping structure on the gate structure. The capping structure includes a capping layer and at least one surface treatment layer stacked on each other. The semiconductor device still includes a dielectric residue protruding from an upper surface of the gate structure and extending into the capping structure. The dielectric residue includes a metal included in the gate structure.

### BRIEF DESCRIPTION OF THE DRAWINGS

The above and other features of the inventive concept will become more apparent by describing in detail exemplary embodiments thereof, with reference to the accompanying drawing, which:

FIG. 1 is a plan view illustrating a semiconductor device in accordance with example embodiments of the present inventive concept;

FIG. 2 is a cross-sectional view illustrating a semiconductor device in accordance with example embodiments of the present inventive concept;

FIGS. 3A, 3B, 4A and 4B are cross-sectional views illustrating semiconductor devices in accordance with example embodiments, respectively of the present inventive concept;

FIGS. 5 to 14 are cross-sectional views illustrating stages of a method of manufacturing a semiconductor device in accordance with example embodiments of the present inventive concept;

FIG. 15 is a cross-sectional view illustrating a semiconductor device in accordance with example embodiments of the present inventive concept;

FIGS. 16 to 18 are cross-sectional views illustrating stages of a method of manufacturing a semiconductor device in accordance with example embodiments of the present inventive concept;

FIG. 19 is a cross-sectional view illustrating a semiconductor device in accordance with example embodiments of the present inventive concept;

FIG. 20 is a cross-sectional view illustrating a semiconductor device in accordance with example embodiments of the present inventive concept; and

FIGS. 21 to 23 are cross-sectional views illustrating stages of a method of manufacturing a semiconductor device in accordance with example embodiments of the present inventive concept.

### DESCRIPTION OF EMBODIMENTS

Exemplary embodiments of the present inventive concept will be described more fully hereinafter with reference to the accompanying drawings. The present disclosure may, however, be embodied in many different forms and should not be constructed as limited to the embodiments set forth herein.

It will be understood that when an element is referred to as being “connected” or “coupled” to another element, it can be directly connected or coupled to the other element or intervening elements may be present. Further, it will be understood that when an element or layer is referred to as being “on,” it may be directly on, or intervening elements or layers may be present.

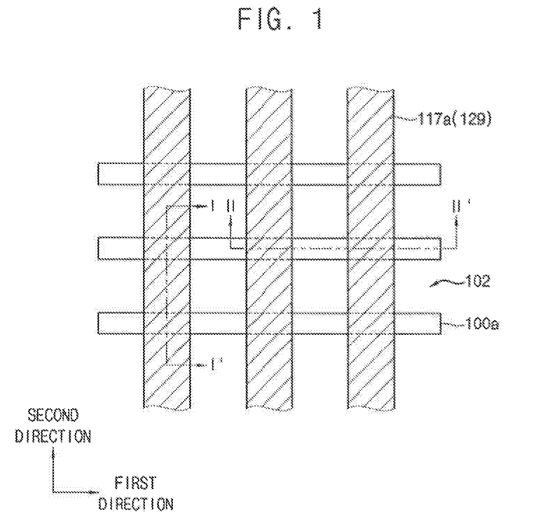

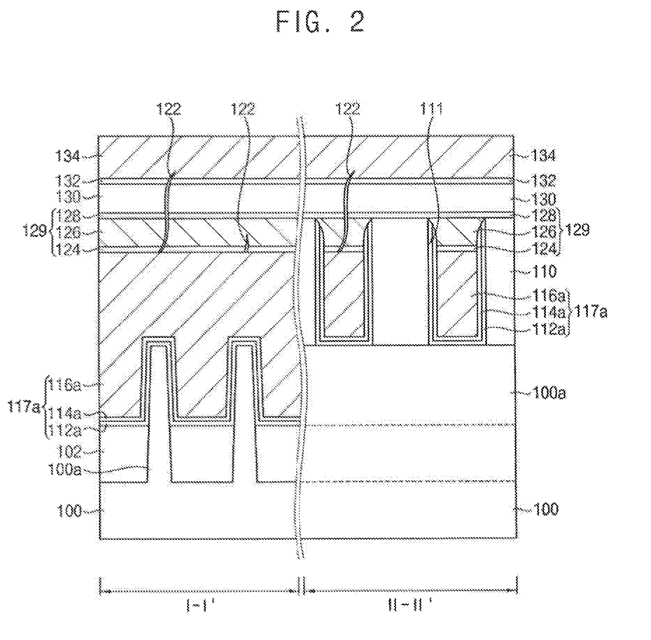

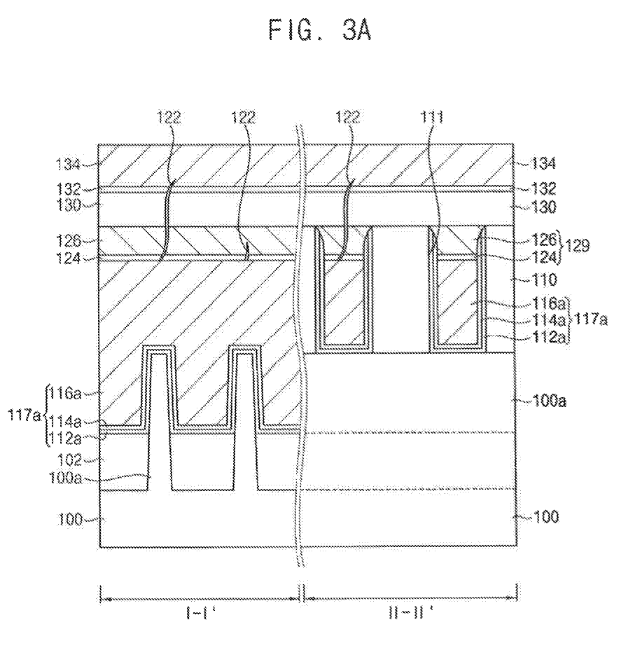

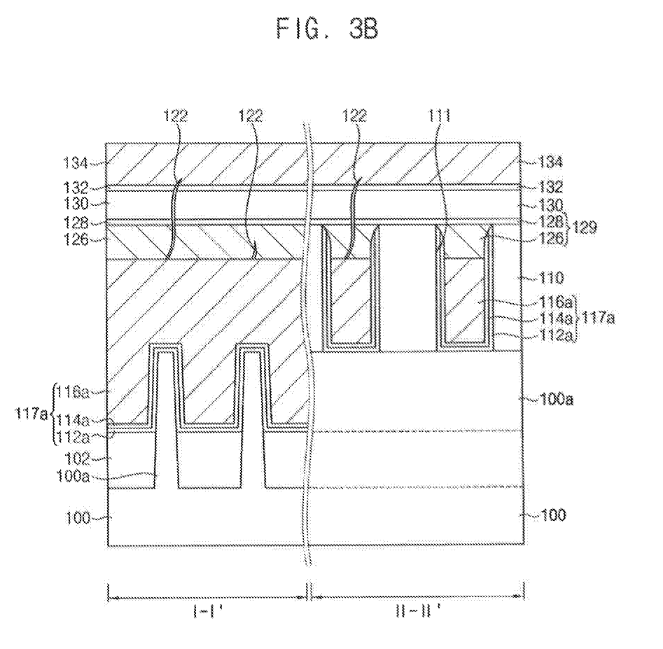

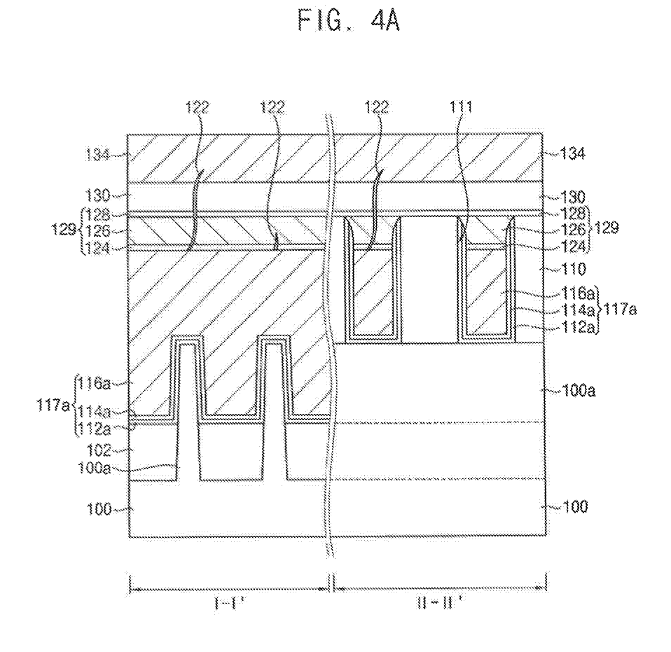

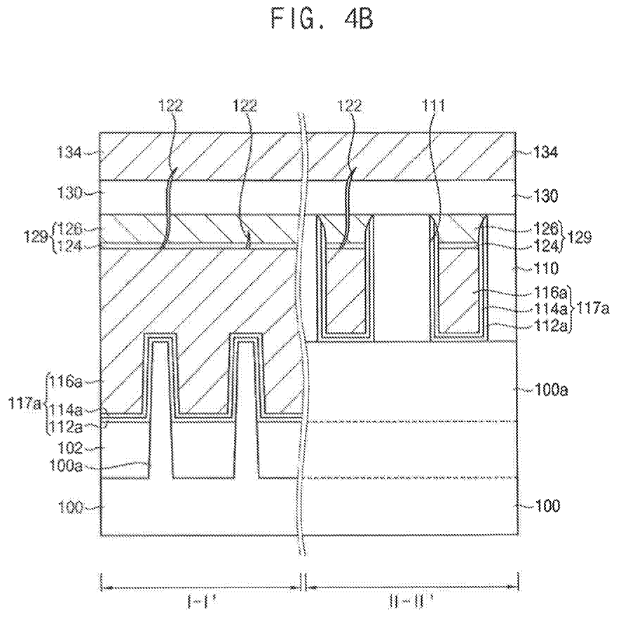

FIG. 1 is a plan view illustrating a semiconductor device in accordance with example embodiments of the present inventive concept. FIG. 2 is a cross-sectional view illustrating a semiconductor device in accordance with example embodiments of the present inventive concept. FIGS. 3A, 3B, 4A and 4B are cross-sectional views, respectively, illustrating semiconductor devices in accordance with example embodiments of the present inventive concept.

Each of FIGS. 2, 3A, 3B, 4A and 4B includes cross-sections taken along lines I-I′ and II-II′ of FIG. 1. The semiconductor device illustrated in FIG. 3A and FIG. 3B may be substantially the same as the semiconductor device illustrated in FIG. 2, except for a stacked structure of a capping structure. The semiconductor device illustrated in FIG. 4A may be substantially the same as the semiconductor device illustrated in FIG. 2, except for a third surface treatment layer. The semiconductor device illustrated in FIG. 4B may be substantially the same as the semiconductor device illustrated in FIG. 2, except for the third surface treatment layer and the stacked structure of the capping structure.

Referring to FIGS. 1 and 2, a plurality of active patterns 100a may protrude upwardly from a surface of a substrate 100. A gate structure 117a may be formed on the active pattern 100a, and may extend in a direction crossing over the active pattern 100a. The gate structure 117a may include a metal. A capping structure 129 may be formed on the gate structure 117a. A dielectric residue 122 may protrude upwardly from an upper surface of the gate structure 117a, and may extend into the capping structure 129. The dielectric residue 122 may include a metal component. The dielectric residue 122 may be formed on one or more of a plurality of gate structures 117a. An upper pattern 134 having electrical conductivity may be formed on the capping structure 129.

The substrate 100 may include a semiconductor material, e.g., silicon, germanium, silicon-germanium, etc., or III-V semiconductor compounds, e.g., GaP, GaAs, GaSb, etc. In some embodiments, the substrate 100 may be a silicon-on-insulator (SOI) substrate, or a germanium-on-insulator (GOI) substrate.

Each of the active patterns 100a may extend in a first direction substantially parallel with an upper surface of the substrate 100 as shown in FIG. 1. The active patterns 100a may be arranged in a second direction which crosses the first direction. In example embodiments, the first and second directions may be perpendicular to each other.

An isolation layer 102 may be formed between the active patterns 100a. The isolation layer 102 may fill a lower portion of a trench between the active patterns 100a. The isolation layer 102 may include an oxide, e.g., a silicon oxide. An active region may be defined as a portion of the active pattern 100a not covered by the isolation layer 102.

A first insulating interlayer 110 may be formed on the active patterns 100a and the isolation layer 102. An upper surface of the first insulating interlayer 110 may be substantially flat. The upper surface of the first insulating interlayer 110 may be higher than upper surfaces of the active patterns 100a. Thus, the first insulating interlayer 110 may cover the active patterns 100a.

The first insulating interlayer 110 may include an opening 111. A sidewall and the upper surface of the active pattern 100a may be exposed to the opening 111.

The gate structure 117a and the capping structure 129 may be formed in the opening 111. The gate structure 117a may extend in the second direction to cross the plurality of active patterns 100a.

The gate structure 117a may include a gate insulation layer 114a and a gate electrode 116a. The gate structure 117a may be positioned at a lower portion of the opening 111. For example, an upper surface of the gate structure 117a may be lower than a top portion of the opening 111.

The gate insulation layer 114a may have a metal oxide having a dielectric constant higher than that of silicon nitride. In example embodiments, a first insulation pattern 112a may be further formed between the gate insulation layer 114a and the active pattern 100a. The first insulation pattern 112a may include, e.g., silicon oxide. The gate insulation layer 114a may include, e.g., hafnium oxide (HfO2), tantalum oxide (Ta2O5), zirconium oxide (ZrO2), etc. The gate insulation layer 114a may surround sidewalls and a bottom of the gate electrode 116a.

The gate electrode 116a may include a metal or a metal nitride. The gate electrode 116a may include, e.g., aluminum (Al), copper (Cu), tantalum (Ta), titanium (Ti), aluminum nitride (AlN), tantalum nitride (TaN), titanium nitride (TiN), etc.

In some example embodiments, a threshold voltage control layer may be further formed on a surface of the gate insulation layer 114a. For example, the threshold voltage control layer may be formed between the gate insulation layer 114a and the gate electrode 116a. A threshold voltage of a transistor may be controlled by the threshold voltage control layer. In example embodiments, the threshold voltage control layer may include a metal, a metal nitride or a metal alloy, e.g., titanium (Ti), titanium nitride (TiN), titanium aluminum nitride (TiAlN), tantalum nitride (TaN), tantalum aluminum nitride (TaAlN), tantalum aluminum carbide (TaAlC), etc.

The capping structure 129 may be formed on an upper surface of the gate electrode 116a. In example embodiments, sidewalls of the capping structure 129 may contact the gate insulation layer 114a.

The capping structure 129 may include a capping layer pattern 126 and at least one of surface treatment layers 124 and 128. For example, the capping structure 129 may include the surface treatment layers 124 and 128 as shown in FIG. 2. The capping layer pattern 126 may include a nitride, e.g., silicon nitride. At least one of the surface treatment layers 124 and 128 may be formed on a surface of a layer exposed during one or more surface treatment processes for changing a metal residue into a dielectric residue. According to the number of the surface treatment process and a material for an underlying layer, etc., a position of the surface treatment layer and a material for the surface treatment layer may be changed.

In example embodiments, the capping structure 129 may have a stacked structure having the capping layer pattern 126 including silicon nitride and at least one of surface treatment layers 124 and 128 including silicon oxynitride formed on the surface of the capping layer pattern 126. The capping layer pattern 126 may directly contact one or more of the surface treatment layers 124 and 128.

In example embodiments, as shown in FIG. 2, the capping structure 129 may include a first surface treatment layer 124, the capping layer pattern 126 and a second surface treatment layer 128 sequentially stacked on the upper surface of the gate electrode 116a.

The first surface treatment layer 124 may be formed by a surface treatment of the gate electrode 116a. Thus, the first surface treatment layer 124 may include a metal included in the gate electrode 116a. In example embodiments, the first surface treatment layer 124 may include a metal oxide, where the metal is included in the gate electrode 116a, a metal nitride, where the metal is included in the gate electrode 116a, or a metal oxynitride, where the metal is included in the gate electrode 116a.

The capping layer pattern 126 may fill a recess over the gate electrode 116a. In example embodiments, an upper surface of the capping layer pattern 126 may be substantially coplanar with the upper surface of the first insulating interlayer 110.

The second surface treatment layer 128 may be formed on the capping layer pattern 126 and the first insulating interlayer 110. The second surface treatment layer 128 may be formed by a surface treatment of the capping layer pattern 126 and the first insulating interlayer 110. In one example, a portion of the second surface treatment layer 128 formed on the capping layer pattern 126 may include a material different from a material of a portion of the second surface treatment layer 128 formed on the first insulating interlayer 110. Also, the second surface treatment layer 128 may include a material different from a material of the first surface treatment layer 124. For example, the portion of the second surface treatment layer 128 formed on the capping layer pattern 126 may include silicon oxynitride, nitrogen-rich silicon nitride, etc. The portion of the second surface treatment layer 128 formed on the first insulating interlayer 110 may include oxygen-rich silicon oxide or silicon oxide including a small amount of nitrogen. In some example embodiments, the second surface treatment layer 128 may be selectively formed on the capping layer pattern 126.

In some example embodiments, as shown in FIG. 3A, the capping structure 129 may include the first surface treatment layer 124 and the capping layer pattern 126 sequentially stacked on the upper surface of the gate electrode 116a. For example, the second surface treatment layer 128 may not be formed on the capping layer pattern 126.

In some example embodiments, as shown in FIG. 3B, the capping structure 129 may include the capping layer pattern 126 and the second surface treatment layer 128 sequentially stacked on the upper surface of the gate electrode 116a. For example, the first surface treatment layer 124 may not be formed on the gate electrode 116a.

A second insulating interlayer 130 may be formed on the capping structure 129. The second insulating interlayer 130 may cover the first insulating interlayer 110. The second insulating interlayer 130 may include, for example, silicon oxide.

In example embodiments, a third surface treatment layer 132 may be formed on the second insulating interlayer 130. The third surface treatment layer 132 may be formed by a surface treatment of the second insulating interlayer 130. The third surface treatment layer 132 may include oxygen-rich silicon oxide or silicon oxide including a small amount of nitrogen.

In some example embodiments, as shown in FIGS. 4A and 4B, the third surface treatment layer may not be formed on the second insulating interlayer 130. As shown in FIG. 4A, the capping structure 129 may include the first surface treatment layer 124, the capping layer pattern 126 and the second surface treatment layer 128. In another embodiment, as shown in FIG. 4B, the capping structure 129 may include the first surface treatment layer 124 and the capping layer pattern 126, not the second surface treatment layer 128.

The upper pattern 134 may be formed on the third surface treatment layer 132.

The upper pattern 134 may include a metal, a metal nitride or a metal silicide. In example embodiments, the upper pattern 134 may serve as a resistor. In some example embodiments, the upper pattern 134 may serve as a conductive pattern. The upper pattern 134 may not be electrically connected with the gate electrode 116a. When the upper pattern 134 serves as the resistor, the upper pattern 134 may include e.g., tungsten, tungsten silicide, tungsten nitride, etc.

The dielectric residue 122 may protrude into the capping structure 129 from the upper surface of the gate structure 117a.

The dielectric residue 122 may be formed by a surface treatment of a metal residue 118 generated from the gate structure 117a. Thus, the dielectric residue 122 may include a metal included in the gate structure 117a. On the other hand, the metal residue may be generated at upper surfaces of some of the plurality of the gate structures 117a, so that the dielectric residue 122 may be formed on the upper surfaces of some of the plurality of the gate structures 117a. For example, the dielectric residue 122 may not be formed on the upper surfaces of the gate structures 117a having no metal residue.

In example embodiments, the dielectric residue 122 may include an oxide of the metal included in the gate structure 117a, a nitride of the metal included in the gate structure 117a or an oxynitride of the metal included in the gate structure 117a.

In example embodiments, the dielectric residue 122 may extend from the upper surface of the gate structure 117a to the upper pattern 134 through the capping structure 129 and the second insulating interlayer 130. For example, the gate structure 117a and the upper pattern 134 may be connected with each other by the dielectric residue 122. However, the dielectric residue 122 may have an insulation property, so that the gate structure 117a and the upper pattern 134 may not be electrically connected with each other.

As described above, the metal residue having conductivity may be prevented from being formed between the gate structure 117a and the upper pattern 134, and the dielectric residue having the insulation property may be formed between the gate structure 117a and the upper pattern 134. Thus, electrical short between the gate structure 117a and the upper pattern 134 due to the metal residue may not occur.

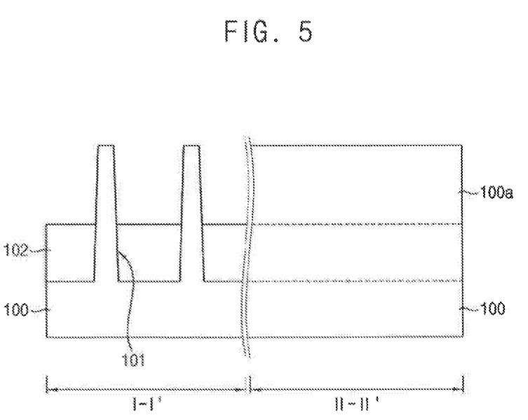

FIGS. 5 to 14 are cross-sectional views illustrating stages of a method of manufacturing a semiconductor device in accordance with example embodiments of the present inventive concept.

Referring to FIG. 5, an upper portion of the substrate 100 may be partially etched to form a trench 101. As the trench 101 is formed on the substrate 100, a plurality of active patterns 100a may be formed on the substrate 100. The plurality of active patterns 100a may extend in the first direction. The isolation layer 102 may be formed to fill a lower portion of the trench 101.

The substrate 100 may include a single crystalline semiconductor material, and the active patterns 100a, which may be formed from the substrate 100, may have single crystallinity.

In example embodiments, the isolation layer 102 may be formed by forming an insulation layer on the substrate 100 to sufficiently fill the trench 101, planarizing the insulation layer until the upper surface of the active patterns 100a may be exposed, and removing an upper portion of the insulation layer to expose upper sidewalls of the active patterns 100a. The insulation layer may be formed of an oxide, e.g., silicon oxide.

In example embodiments, the isolation layer 102 may be formed to have a multi-layered structure. For example, the isolation layer 102 may be formed by conformally forming an insulation liner on an inner wall of the trench 101, and forming an insulation pattern on the insulation liner to partially fill the trench 101. The insulation liner may include, e.g., silicon oxide, silicon nitride, etc.

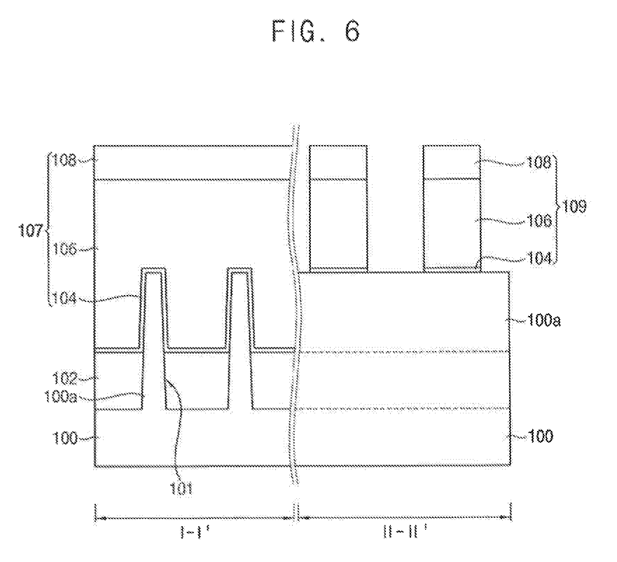

Referring to FIG. 6, a dummy gate structure 109 may be formed on the active patterns 100a and the isolation layer 102. The dummy gate structure 109 may include a dummy gate insulation pattern 104, a dummy gate electrode 106 and a hard mask 108 sequentially stacked.

In example embodiments, a dummy gate insulation layer may be conformally formed on the active patterns 100a and the isolation layer 102. The dummy gate insulation layer may be formed of, e.g., silicon oxide. In example embodiments, the dummy gate insulation layer may be formed by a thermal oxidation process, a chemical vapor deposition (CVD) process or an atomic layer deposition (ALD) process. A dummy gate electrode layer may be formed on the dummy gate insulation layer. The dummy gate electrode layer may be formed to sufficiently fill the trenches 101. An upper surface of the dummy gate electrode layer may be higher than an upper surface of each of the active patterns 100a. The dummy gate electrode layer may be formed of, e.g., polysilicon. The dummy gate electrode layer may be formed by the CVD process or the ALD process. The hard mask 108 may be formed on the dummy gate electrode layer, and the dummy gate electrode layer and the dummy gate insulation layer may be patterned using the hard mask 108 as an etching mask to form the dummy gate structure 109.

The dummy gate structure 109 may extend to cross the active patterns 100a. In example embodiments, the dummy gate structure 109 may extend in the second direction when viewed in the directions shown in FIG. 1. A plurality of dummy gate structures 109 may be spaced apart from each other in the first direction.

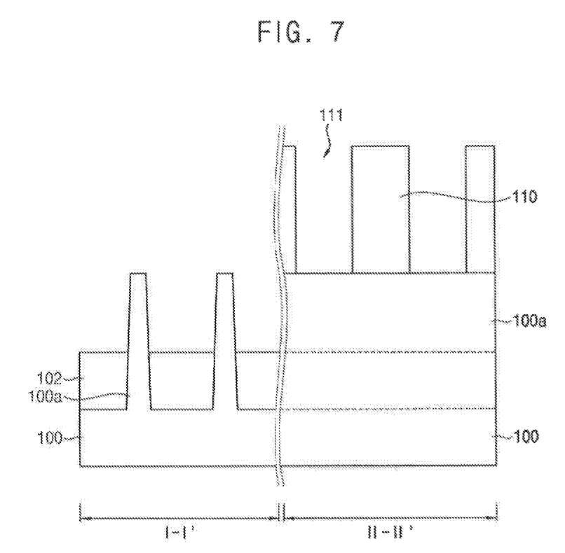

Referring to FIG. 7, the first insulating interlayer 110 may be formed to fill a gap between the dummy gate structures 109. The first insulating interlayer 110 may be planarized until an upper surface of the dummy gate structures 109 may be exposed. The dummy gate structure 109 may be isotropically etched to form an opening Ill. An upper surface and upper sidewalls of the active pattern 100a may be exposed by the opening 111. In one embodiment, the opening 111 may extend in the second direction.

The planarization process may be performed by a chemical mechanical polishing (CMP) process and/or an etch back process. The first insulating interlayer 110 may be formed of, e.g., silicon oxide. The first insulating interlayer 110 may be formed by the CVD process, then ALD process or a spin on glass (SOG) process, etc.

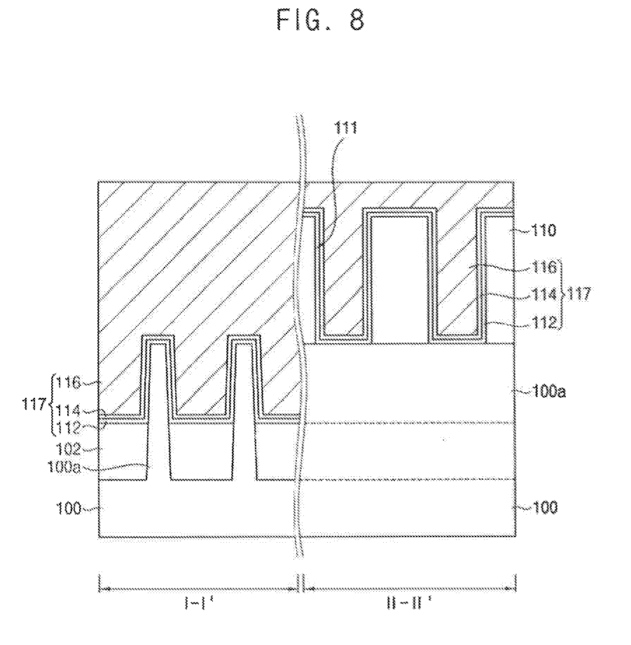

Referring to FIG. 8, the preliminary gate structure 117 may be formed on the first insulating interlayer 110 to fill the opening 111.

Particularly, a first insulation layer 112 may be conformally formed on an inner wall of the opening 111 and a surface of the first insulating interlayer 110. The first insulation layer 112 may be formed of, e.g., silicon oxide. The first insulation layer 112 may be formed by the CVD process, the ALD process or the thermal oxidation process. When the first insulation layer 112 is formed by the thermal oxidation process, the first insulation layer 112 may be formed on exposed surfaces of the active patterns 100a. A preliminary gate insulation layer 114 may be conformally formed on the first insulation layer 112. A preliminary gate electrode layer 116 may be formed on the preliminary gate insulation layer 114 to sufficiently fill the opening 111.

The preliminary gate insulation layer 114 may be formed of a metal oxide, e.g., hafnium oxide (HfO2), tantalum oxide (Ta2O5), zirconium oxide (ZrO2), etc. The preliminary gate insulation layer 114 may be formed by the CVD process or the ALD process.

The preliminary gate electrode layer 116 may be formed of a metal or a metal nitride, e.g., aluminum (Al), copper (Cu), tantalum (Ta), titanium (Ti), aluminum nitride, tantalum nitride, etc. The preliminary gate electrode layer 116 may be formed by the CVD process, the ALD process or a physical vapor deposition (PVD) process.

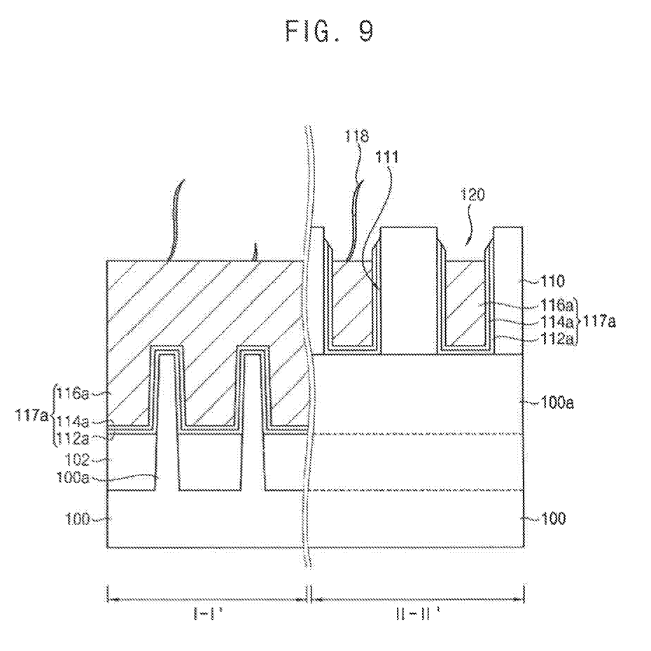

Referring to FIG. 9, an upper portion of the preliminary gate structure 117 may be partially removed to form a gate structure 117a in a lower portion of the opening 111. The gate structure 117a may include a first insulation pattern 112a, a gate insulation layer 114a and a gate electrode 116a sequentially stacked. Metal residues 118 may be formed on one or more of a plurality of gate structures 117a. A recess 120 may be formed over the gate structure 117a.

In example embodiments, the preliminary gate structure 117 may be planarized until the upper surface of the first insulating interlayer 110 may be exposed. Thus, after the planarization process, the preliminary gate structure 117 may only remain in the opening 111. In example embodiments, the planarization process may be performed by the chemical mechanical polishing (CMP) process and/or the etch back process. Portions of the first insulation layer 112, the preliminary gate insulation layer 114 and the preliminary gate electrode layer 116 at an upper portion of the opening 111 may be partially etched to form the gate structure 117a. The gate structure 117a may include the first insulation pattern 112a, the gate insulation layer 114a and the gate electrode 116a sequentially stacked. Then upper surface of the gate structure 117a may be lower than the upper surface of the first insulating interlayer 110 surrounding the gate structure 117a. Thus, the recess 120 may be formed over the gate structure 117a. The partial etching of the first insulation layer 112, the preliminary gate insulation layer 114 and the preliminary gate electrode layer 116 may be performed by, for example, the etch back process. The etch back process may include an anisotropic etching process.

However, when the preliminary gate structures 117 are etched, metals removed from the preliminary gate structure 117 or reactants in the etching process may not be discharged. Thus, the metal residue 118 may be generated on one or more of the gate structures 117a. The metal residue 118 may be formed from the metal included in the preliminary gate structure 117, so that the metal residue 118 may include metal components included in the preliminary gate structure 117. For example, the metal residue 118 may have metal components included in the preliminary gate insulation layer 114 and/or the preliminary gate electrode layer 116. Thus, the metal residue 118 may have conductivity. For example, the metal residue 118 may have electrical conductivity.

The metal residue 118 may irregularly protrude from the upper surfaces of one or more of the gate structures 117a. The metal residue 118 may strongly contact the gate structure 117a, and thus the metal residue 118 may not be easily removed during subsequent etching processes. Being electrically conductivity, the metal residue 118 may cause electrical short.

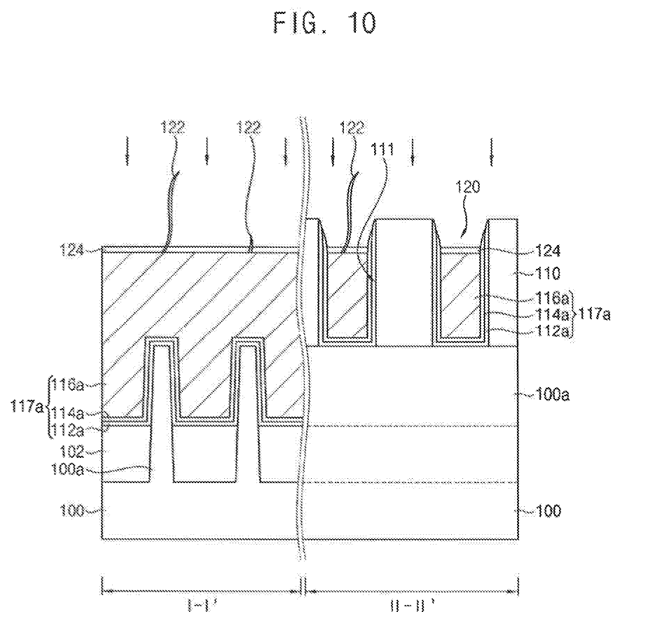

Referring to FIG. 10, a first surface treatment may be performed on the gate structure 117a, so that the metal residue 118 on the gate structure 117a may be transformed into a dielectric material. Thus, the first surface treatment layer 124 may be formed on the gate structure 117a, and the metal residue 118 may be transformed into the dielectric residue 122.

The first surface treatment may include various treatment processes that may change the metal residue 118 into the dielectric residue 122. The metal included in the metal residue 118, for example, the metal included in the gate structure 117a may be changed into an insulation material by the first surface treatment. For example, one or more metals included in the gate electrode 116a and the gate insulation layer 114a may be changed into the insulation material by the first surface treatment. Thus, the first surface treatment may be differently performed depending on the metal included in the gate structure 117a.

In example embodiments, the first surface treatment may include, e.g., an oxidation process, a nitridation process or an oxynitridation process using oxygen and nitrogen. In example embodiments, the first surface treatment may include a plasma treatment using O₂, N₂, N₂O or NH₃. In some example embodiments, the first surface treatment may include a deposition process. For example, the first surface treatment may include the ALD process for forming an oxide layer, a nitride layer or an oxynitride layer. In the ALD process, the metal residue 118 may be reacted with source gases for deposition to form the dielectric residue 122.

Materials included in the first surface treatment layer 124 may be changed in accordance with the conditions of the first surface treatment and the material of the exposed gate structure 117a. For example, the first surface treatment layer 124 may include an oxide of the material of the exposed gate structure 117a, a nitride thereof or an oxynitride thereof.

When the gate electrode 116a includes, e.g., titanium and the gate insulation layer 114a includes, e.g., aluminum oxide, the first surface treatment may include the oxidation process in which titanium and aluminum may be transformed into an insulator. However, titanium may be transformed into titanium nitride having the conductivity by the nitridation process, and the nitridation process may not be appropriate as the first surface treatment. Instead, the first surface treatment layer 124 including titanium oxide and/or aluminum oxide having the insulation property may be formed on the gate electrode 116a by the first surface treatment.

The dielectric residue 122 may include a metal included in the metal residue 118. The metal residue 118 may include the metal included in the gate structure 117a. For example, the dielectric residue 122 may be the oxide of the metal residue, the nitride thereof or the oxynitride thereof.

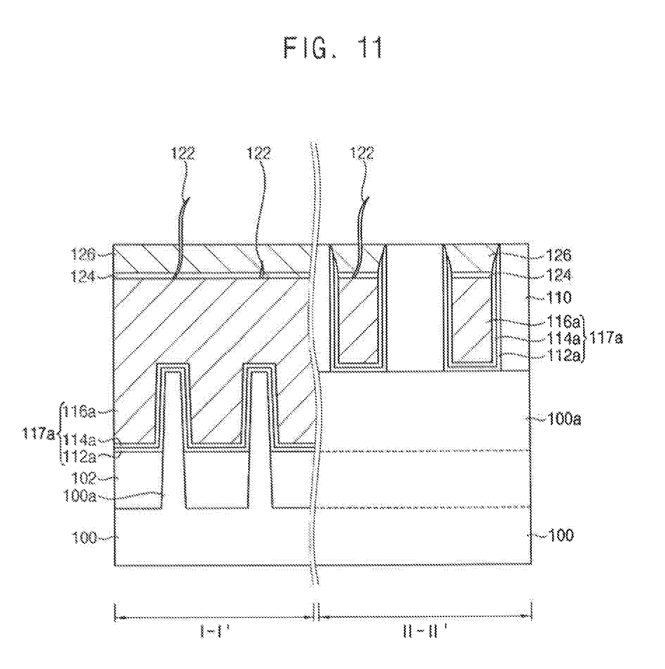

Referring to FIG. 11, a capping insulation layer may be formed on the first surface treatment layer 124 to fill the recess 120. The capping insulation layer may be planarized until the upper surface of the first insulating interlayer 110 may be exposed to form the capping layer pattern 126 on the first surface treatment layer 124.

The capping insulation layer may include a nitride, e.g., silicon nitride. The capping insulation layer may be formed by the CVD process or the ALD process. The planarization process may include the CMP process and/or the etch back process.

In example embodiments, the dielectric residues 122 may not be removed during the formation of the capping layer pattern 126. In example embodiments, one or more of the dielectric residues 122 may have the insulation property after forming the capping layer pattern 126. However, others of the dielectric residues 122 may be reduced to a metal, and a reduced portion of the dielectric residues 122 may have conductivity.

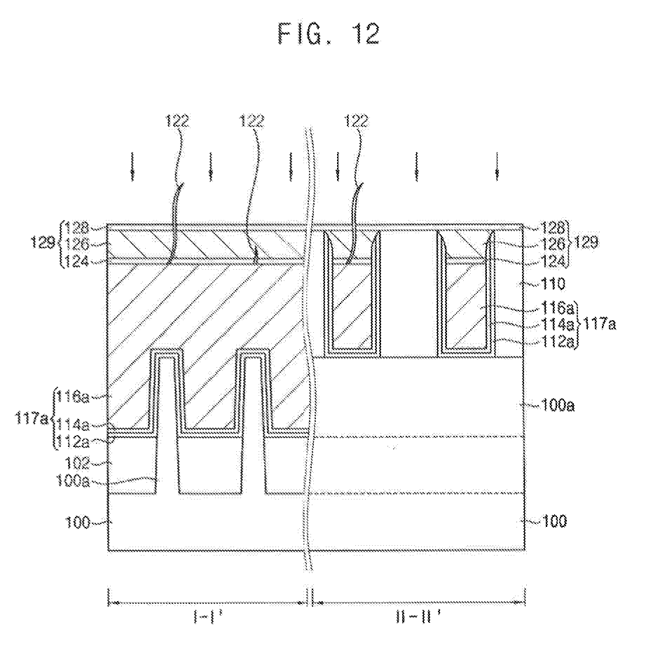

Referring to FIG. 12, a second surface treatment may be performed on the capping layer pattern 126 and the first insulating interlayer 110, so that the reduced portion of the dielectric residues 122 may be transformed into a dielectric material. Thus, a second surface treatment layer 128 may be formed on the capping layer pattern 126 and the first insulating interlayer 110.

In example embodiments, the second surface treatment may include, e.g., the oxidation process, the nitridation process or the oxynitridation process using oxygen and nitrogen. Thus, the second surface treatment layer 128 may include silicon oxynitride, nitride rich silicon nitride, etc. In example embodiments, the second surface treatment may include the plasma treatment. In some example embodiments, the second surface treatment may include the deposition process.

When the capping layer pattern 126 includes silicon nitride and the second surface treatment is the oxidation process, the second surface treatment layer 128 including the silicon oxynitride may be formed on the capping layer pattern 126.

In some example embodiments, during the second surface treatment process, only the upper surface of the capping layer pattern 126 may be reacted, so that the second surface treatment layer 128 may not be formed on the first insulating interlayer 110.

The second surface treatment may be further performed to maintain the insulation property of the dielectric residue 122. In some example embodiments, the second surface treatment may not be performed. For example, the second surface treatment layer 128 may not be formed on the capping layer pattern 126. Thereafter, subsequent processes may be performed to form the semiconductor device shown in FIG. 3A.

In some example embodiments, the first surface treatment may not be performed, and the capping layer pattern 126 may be formed on the gate structure 117a. The second surface treatment may be performed on the capping layer pattern 126, so that the second surface treatment layer 128 may be formed on the capping layer pattern 126. Thereafter, subsequent processes are performed to form the semiconductor device shown in FIG. 3B.

As described above, the capping layer pattern 126 and at least one of surface treatment layers 124 and 128 may be formed on the gate structure 117a. The stack structure including the capping layer pattern 126 and at least one of surface treatment layers 124 and 128 may serve as the capping structure 129.

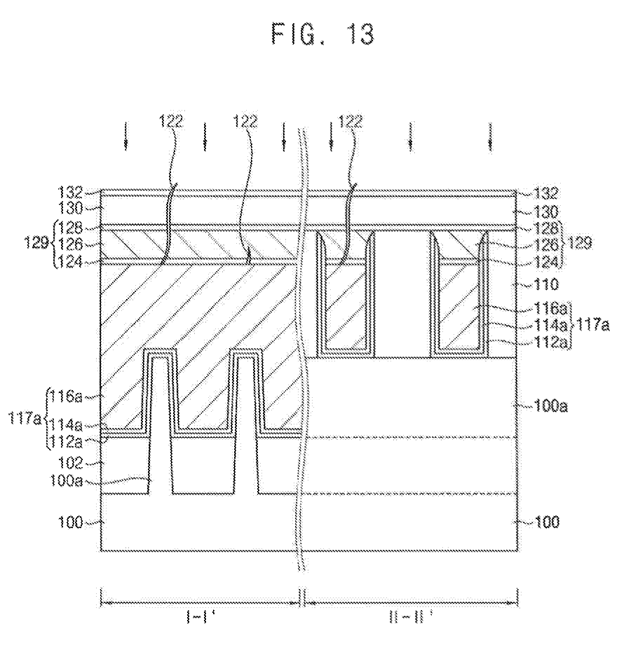

Referring to FIG. 13, the second insulating interlayer 130 may be formed on the second surface treatment layer 128. A third surface treatment may be performed on a surface of the second insulating interlayer 130 to form the third surface treatment layer 132.

In example embodiments, the second insulating interlayer 130 may be formed of, e.g., silicon oxide. The second insulating interlayer 130 may be formed by the CVD process, a spin coating process or the ALD process.

In example embodiments, the third surface treatment may include, e.g., the oxidation process, the nitridation process or the oxynitridation process using oxygen and nitrogen. In example embodiments, the third surface treatment may include the plasma treatment. In some example embodiments, the third surface treatment may include the deposition process. Thus, the third surface treatment layer 132 may include oxygen-rich silicon oxide or silicon oxynitride.

During the formation of the second insulating interlayer 130, a portion of the dielectric residue 122 may keep the insulation property. However, a portion of the dielectric residue 122 may be reduced to a metal having conductivity. The metal that is reduced may be transformed into a dielectric material by the third surface treatment, and the dielectric residue 122 may have the insulation property.

As described above, the first, second and third treatments may be performed to transform the metal residue 118 into the dielectric residue 122.

In example embodiments, after forming the gate structure, the surface treatments may be performed before and/or after performing subsequent processes so that the dielectric residue 122 may have the insulation property. In some example embodiments, at least one of the first, second and third surface treatments may be performed to simplify the processes. If the surface treatment is not performed, a surface treatment layer may not be formed by the surface treatment.

In example embodiments, the first and second surface treatments may be performed, and the third surface treatment may not be performed. In this case, the first and second surface treatment layers 124 and 128 may be formed, and the third surface treatment layer may not be formed, as shown in FIG. 4A. In some example embodiments, the first surface treatment may be performed, and the second and third surface treatments may not be performed. In this case, the first surface treatment layer 124 may be formed, and the second and third surface treatment layers may not be formed, as shown in FIG. 4B. In some example embodiments, the second surface treatment may be performed, and the first and third surface treatments may not be performed. In this case, the second surface treatment layer 128 may be formed, and the first and third surface treatment layers may not be formed.

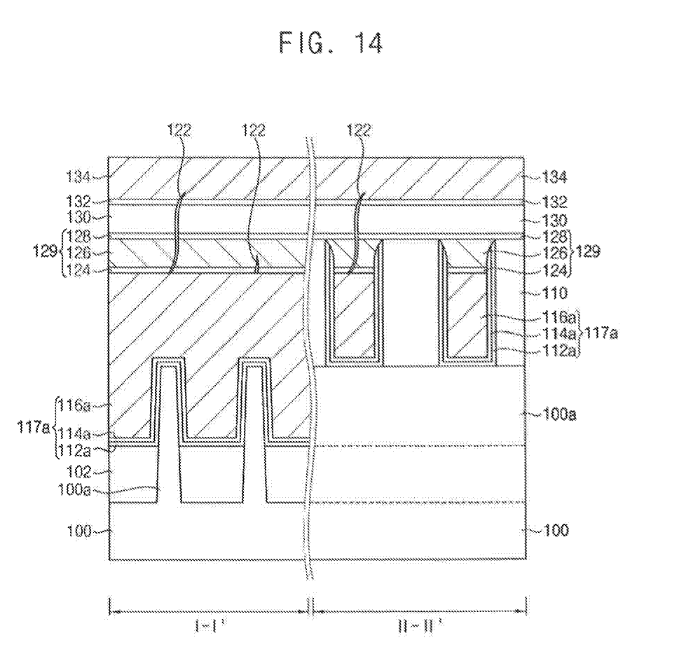

Referring to FIG. 14, an upper pattern 134 having conductivity may be formed on the third surface treatment layer 132. In example embodiments, the upper pattern 134 may include a resistive metal.

In example embodiments, an upper layer having conductivity may be formed on the third surface treatment layer 132. The upper layer may be patterned to form the upper pattern 134. A portion of a lower surface of the upper pattern 134 may be overlapped with the upper surface of the gate structure 117a.

In example embodiments, the resistive metal included in the upper pattern 134 may include, e.g., tungsten, tungsten nitride, etc.

In example embodiments, the dielectric residue 122 may be formed between the upper pattern 134 and the gate structure 117a. In example embodiments, the dielectric residue 122 may extend from the upper surface of the gate structure 117a to a lower portion of the upper pattern 134 through the capping structure 129. However, the dielectric residue 122 may have the insulation property, so that the gate structure 11a and the upper pattern 134 may not be electrically connected with each other. Thus, an electric operation failure due to the dielectric residue 122 may not occur.

As described above, the metal residue having conductivity may not be formed between the gate structure 117a and the upper pattern 134, and the dielectric residue 122 having the insulation property may be formed between the gate structure 117a and the upper pattern 134. The capping structure 129 on the gate structure 117a may include at least one surface treatment layer.

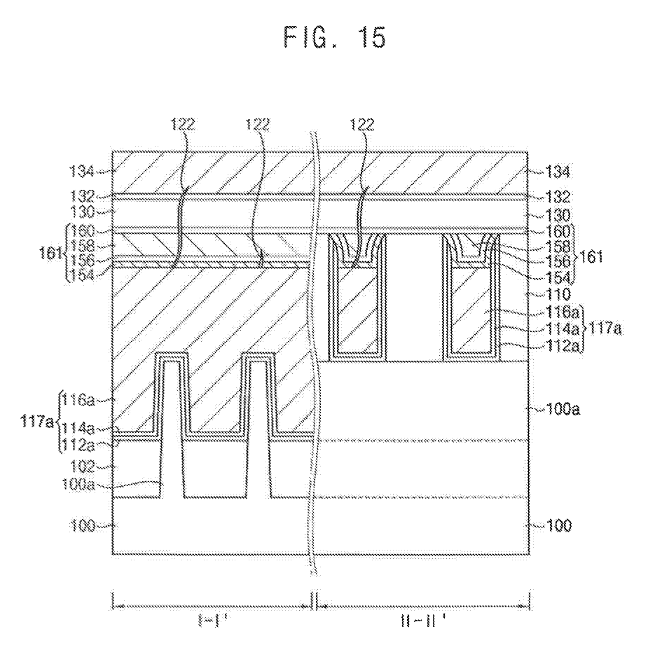

FIG. 15 is a cross-sectional view illustrating a semiconductor device in accordance with example embodiments.

The semiconductor device illustrated in FIG. 15 may be substantially the same as the semiconductor device illustrated in FIG. 2, except for a stacked structure of a capping structure. Hereinafter, the capping structure is mainly described.

Referring to FIG. 15, a capping structure 161 may be formed on the upper surface of the gate electrode 116a. The capping structure 161 may fill the recess. The capping structure 161 may have a stacked structure including a capping liner layer 154, a first surface treatment layer 156, a capping layer pattern 158 and a second surface treatment layer 160.

The capping liner layer 154 and the first surface treatment layer 156 may be conformally formed on an inner wall of the recess. In example embodiments, the capping liner layer 154 may be formed on the upper surface of the gate electrode 116a and the gate insulation layer 114a.

In example embodiments, the capping liner layer 154 may include, for example, silicon nitride. The first surface treatment layer 156 may be formed by a surface treatment of the capping liner layer 154. The first surface treatment layer 156 may include, e.g., silicon oxynitride, nitride rich silicon nitride, etc.

The capping layer pattern 158 may fill the recess. The capping layer pattern 158 may include silicon nitride.

The second surface treatment layer 160 may be formed on the capping layer pattern 158 and the first insulating interlayer 110. In some example embodiments, the second surface treatment layer 160 may not be formed.

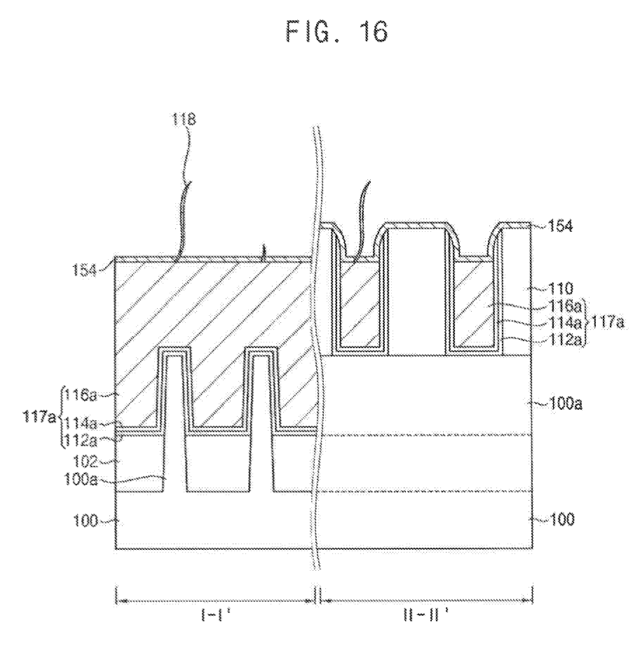

FIGS. 16 to 18 are cross-sectional views illustrating stages of a method of manufacturing a semiconductor device in accordance with example embodiments of the present inventive concept.

Referring to FIG. 16, processes substantially the same as or similar to those illustrated with reference to FIGS. 5 to 9 may be performed. The capping liner layer 154 may be formed on the gate insulation layer 114a, the gate electrode 116a and the first insulating interlayer 110 exposed by the recess. The capping liner layer 154 may be formed of, for example, silicon nitride. The capping liner layer 154 may be formed by the CVD process or the ALD process.

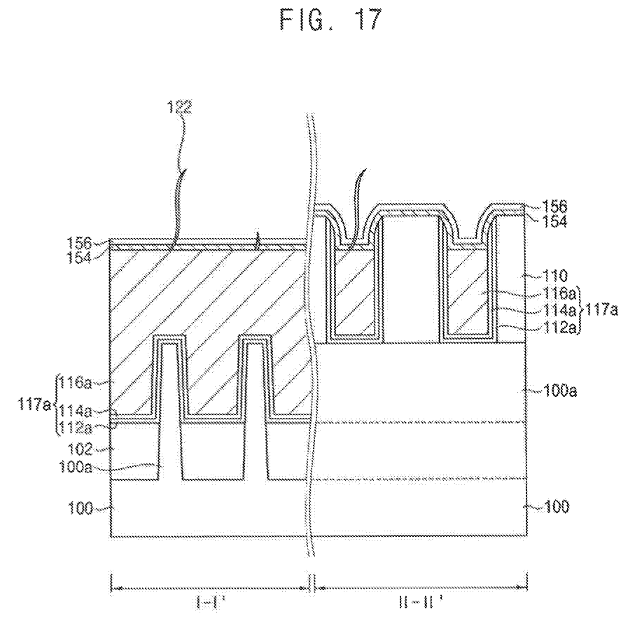

Referring to FIG. 17, a first surface treatment may be performed on the gate structure 117a, so that the metal residue 118 on the gate structure 117a may be transformed into a material having the insulation property. The first surface treatment layer 156 may be formed on the capping liner layer 154, and the metal residue 118 may be transformed into the dielectric residue 122.

The first surface treatment with reference to FIG. 17 may be substantially the same as or similar to the first surface treatment illustrated with reference to FIG. 10. The first surface treatment layer 156 may be formed on the capping liner layer 154, and the capping liner layer 154 may include, for example, silicon nitride by the first surface treatment. The first surface treatment layer 156 may include, for example, oxide, nitride or oxynitride included in the capping liner layer 154. In example embodiments, the first surface treatment layer 156 may include, e.g., silicon oxynitride, nitrogen-rich silicon nitride, etc.

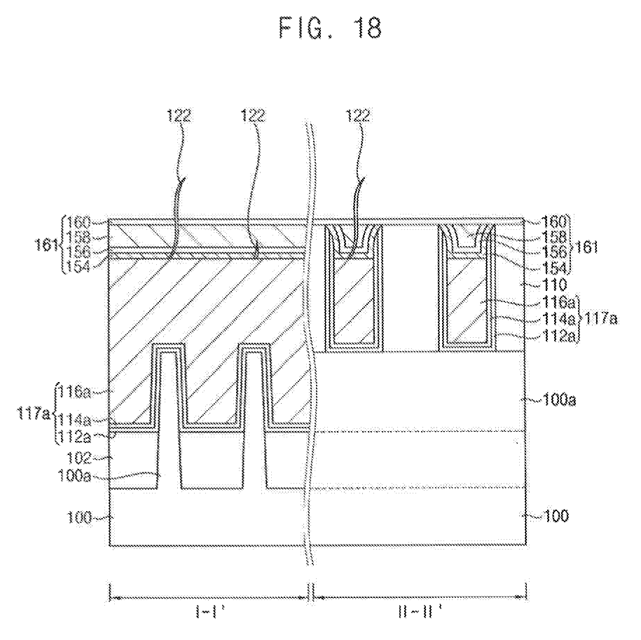

Referring to FIG. 18, the capping insulation layer may be formed on the first surface treatment layer 156 to fill the recess 120. The capping insulation layer, the first surface treatment layer 156 and the capping liner layer 154 may be planarized until the upper surface of the first insulating interlayer 110 may be exposed. Thus, the first surface treatment layer 156 and the capping liner layer 154 on the first insulating interlayer 110 may be removed. The capping layer pattern 158 may be formed on the first surface treatment layer 156. The planarization process may be substantially the same as or similar to the planarization process illustrated with reference to FIG. 11.

Then, processes substantially the same as or similar to those illustrated with reference to FIGS. 12 to 14 may be performed to form the semiconductor device shown in FIG. 15.

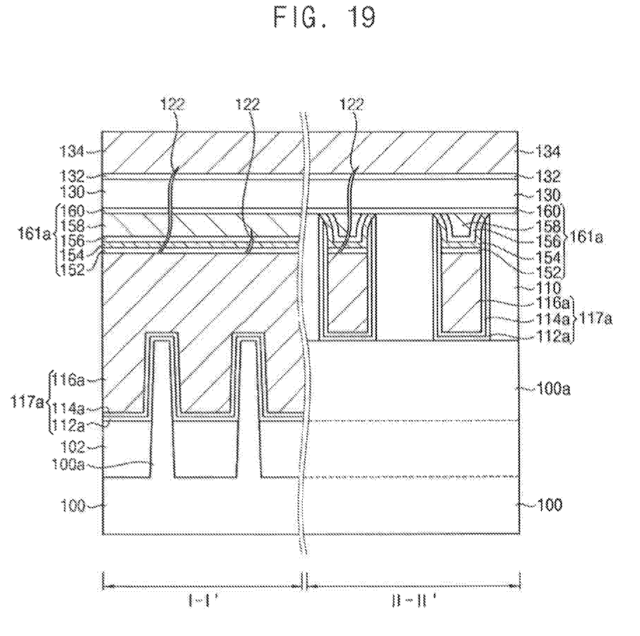

FIG. 19 is a cross-sectional view illustrating a semiconductor device in accordance with example embodiments of the present inventive concept.

The semiconductor device illustrated in FIG. 19 may be substantially the same as the semiconductor device illustrated in FIG. 15, except for a stacked structure of a capping structure 161a. Hereinafter, the capping structure is mainly described.

Referring to FIG. 19, the capping structure 161a may have the stacked structure including a lower surface treatment layer 152, the capping liner layer 154, the first surface treatment layer 156, the capping layer pattern 158 and the second surface treatment layer 160. For example, the capping structure 161a may include the lower surface treatment layer 152 in addition to the capping structure illustrated in FIG. 15.

The lower surface treatment layer 152 may be formed by a surface treatment of the upper surface of the gate electrode 116a. Thus, the lower surface treatment layer 152 may include a metal included in the gate electrode 116a. In example embodiments, the lower surface treatment layer 152 may include an oxide of the metal included in the gate electrode 116a, a nitride of the metal included in the gate electrode 116a, or an oxynitride of the metal included in the gate electrode 116a.

A method of manufacturing the semiconductor device shown in FIG. 19 may be substantially the same as or similar to the method of manufacturing the semiconductor device shown in FIG. 15, except for further formation of the lower surface treatment layer 152 on the gate electrode 116a.

For example, processes illustrated with reference to FIGS. 5 to 9 may be performed to form the gate structure 117a, and the lower surface treatment layer 152 may be formed on the gate structure 117a by processes illustrated with reference to FIG. 10. During the formation of the lower surface treatment layer 152, the metal residue may be transformed into the dielectric residue 122. Processes illustrated with reference to FIGS. 16 to 18 may be performed to form the semiconductor device shown in FIG. 19.

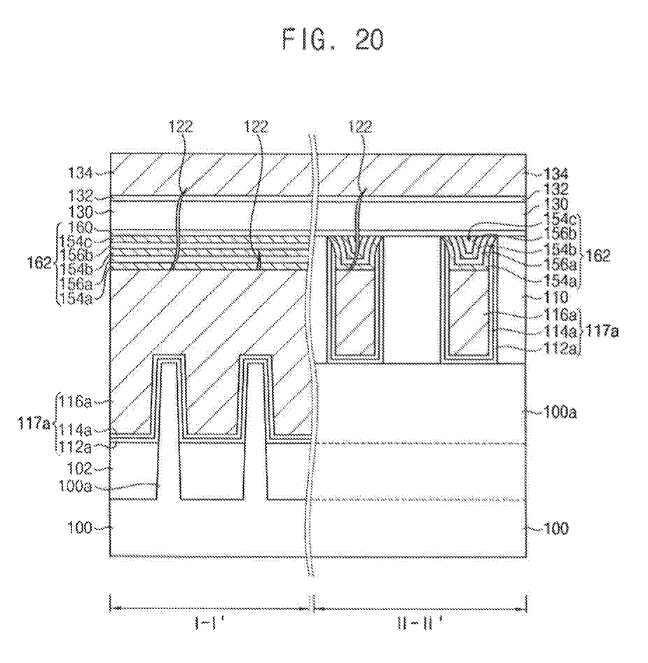

FIG. 20 is a cross-sectional view illustrating a semiconductor device in accordance with example embodiments of the present inventive concept.

The semiconductor device illustrated in FIG. 20 may be substantially the same as the semiconductor device illustrated in FIG. 2, except for a stacked structure of a capping structure 162. Hereinafter, the capping structure is mainly described.

Referring to FIG. 20, the capping structure 162 may be formed on the upper surface of the gate electrode 116a. The capping structure 162 may fill the recess. The capping structure 162 may include a capping liner layer and a lower surface treatment layer alternately and repeatedly stacked on each other. In example embodiments, the capping structure 162 may have a first capping liner layer 154a, a first lower surface treatment layer 156a, a second capping liner layer 154b, a second lower surface treatment layer 156b and a third capping liner layer 154c.

The first to third capping liner layers 154a, 154b and 154c and the first and second lower surface treatment layers 156a and 156b may be conformally formed on the inner wall of the recess in the first insulating interlayer 110.

In example embodiments, the first to third capping liner layers 154a, 154b and 154c may include silicon nitride. The first and second lower surface treatment layers 156a and 156b may be formed by surface treatments of the capping liner layer thereunder, respectively. Thus, the first and second lower surface treatment layers 156a and 156b may include silicon oxynitride or nitrogen-rich silicon nitride.

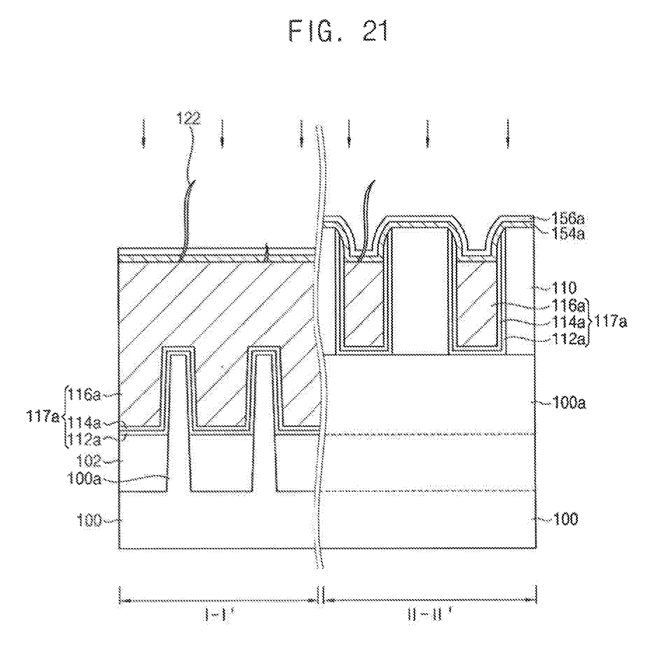

FIGS. 21 to 23 are cross-sectional views illustrating stages of a method of manufacturing a semiconductor device in accordance with example embodiments of the present inventive concept.

Referring to FIG. 21, processes illustrated with reference to FIGS. 5 to 9 may be performed to form the gate structure. The first capping liner layer 154a may be formed on the gate insulation layer 114a and the gate electrode 116a exposed by the recess. The first capping liner layer 154a may include, for example, silicon nitride. The first capping liner layer 154a may be formed by the CVD process or the ALD process.

A first surface treatment may be performed on the gate structure 117a, so that the metal residue on the gate structure 117a may be transformed into a material having the insulation property. Thus, the first lower surface treatment layer 156a may be formed on the capping liner layer 154a, and the metal residue may be transformed into the dielectric residue 122. The first surface treatment may be substantially the same as or similar to the first surface treatment illustrated with reference to FIG. 10.

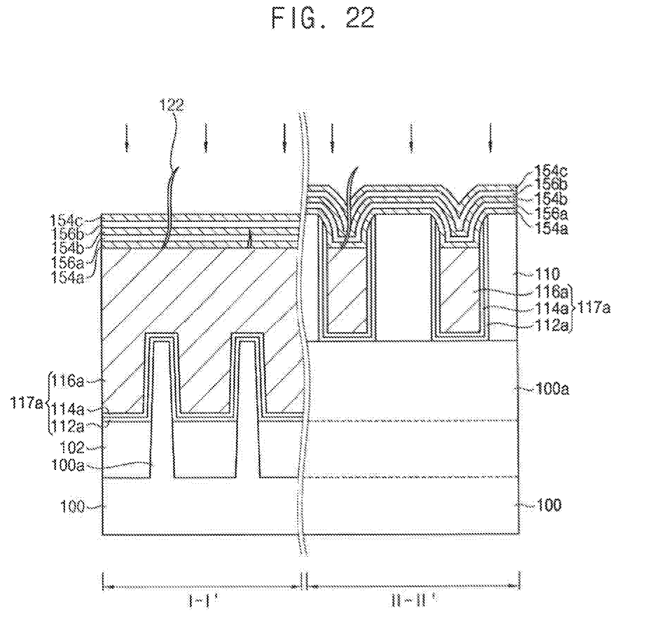

Referring to FIG. 22, the second capping liner layer 154b may be formed on the first lower surface treatment layer 156a. A second surface treatment may be performed on the second capping liner layer 154b to form the second lower surface treatment layer 156b. The third capping liner layer 154c may be formed on the second lower surface treatment layer 156b. In example embodiments, the third capping liner layer 154c may fill the recess.

In some example embodiments, the capping liner layer and the surface liner layer may be alternately and repeatedly formed on each other until the recess may be completely filled.

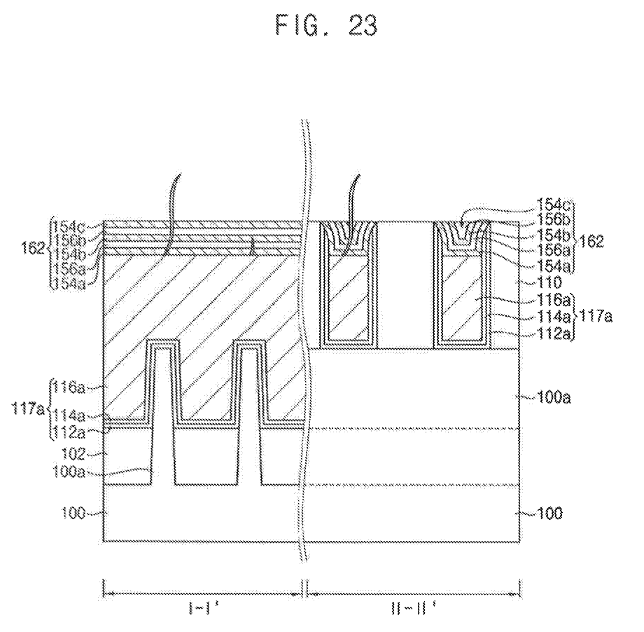

Referring to FIG. 23, upper surfaces of the first to third capping liner layers 154a, 154b and 154c and the first and second lower surface treatment layers 156a and 156b may be planarized until the upper surface of the first insulating interlayer 110 may be exposed. Thus, the first to third capping liner layers 154a, 154b and 154c and the first and second lower surface treatment layers 156a and 156b on the first insulating interlayer 110 may be removed, and a capping structure including capping liner layers 154a, 154b and 154c and the lower surface treatment layers 156a and 156b alternatively and repeatedly stacked on each other may be formed. The planarization process may include the CMP process and/or the etch back process.

Processes illustrated with reference to FIGS. 12 to 14 may be performed to form the semiconductor device shown in FIG. 20.

The semiconductor device in accordance with example embodiments may be used in memory devices or logic devices including a finFET.

The foregoing is illustrative of example embodiments and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A semiconductor device, comprising:
a plurality of active patterns protruding from a surface of a substrate;
a gate structure on the active patterns, the gate structure crossing over the active patterns and including a first metal;
a capping structure on the gate structure; and
a dielectric residue protruding from an upper surface of the gate structure and extending into the capping structure, the dielectric residue including a second metal.

2. The semiconductor device of claim 1, further comprising an insulating interlayer covering sidewalls and upper surfaces of the active patterns, wherein the insulating interlayer includes an opening exposing surfaces of the active patterns, and the gate structure and the capping structure are formed in the opening.

3. The semiconductor device of claim 1, wherein the gate structure includes a gate insulation layer and a gate electrode including the first metal.

4. The semiconductor device of claim 1, wherein the second metal included in the dielectric residue is substantially the same as the first metal included in the gate structure.

5. The semiconductor device of claim 3, further comprising a metal oxide layer contacting the upper surface of the gate structure.

6. The semiconductor device of claim 1, wherein the dielectric residue includes a metal oxide, a metal nitride or a metal oxynitride.

7. The semiconductor device of claim 1, wherein the capping structure includes a capping layer and at least one surface treatment layer stacked on each other.

8. The semiconductor device of claim 7, wherein the capping layer includes silicon nitride, and the at least one surface treatment layer includes silicon oxynitride.

9. The semiconductor device of claim 1, further comprising:
an upper insulating interlayer covering the capping structure; and
an upper pattern having conductivity on the upper insulating interlayer.

10. A semiconductor device, comprising:
a plurality of active patterns protruding from a surface of a substrate;
an insulating interlayer covering sidewalls and upper surfaces of the active patterns, wherein the insulating interlayer includes an opening extending in a direction crossing an extension direction of the active patterns;
a gate structure in the opening, the gate structure including a gate insulation layer and a gate electrode; and
a capping structure on the gate structure, wherein the capping structure includes a capping layer and at least one surface treatment layer stacked on each other.

11. The semiconductor device of claim 10, further comprising a dielectric residue protruding from an upper surface of the gate structure and extending into the capping structure, the dielectric residue including a first metal.

12. The semiconductor device of claim 11, wherein the gate insulation layer includes a metal oxide, and the gate electrode includes a second metal.

13. The semiconductor device of claim 12, wherein the first metal included in the dielectric residue is substantially the same as the second metal included in the gate structure.

14. The semiconductor device of claim 10, wherein the capping layer has a pillar shape filling the opening, and the surface treatment layer is formed on a surface of the capping layer.

15. The semiconductor device of claim 10, wherein the capping layer is formed on a sidewall of the opening and an upper surface of the gate structure, and the surface treatment layer is formed on a surface of the capping layer.

16. The semiconductor device of claim 10, wherein the capping layer includes silicon nitride, and the surface treatment layer includes silicon oxynitride.

17. A semiconductor device, comprising:
a plurality of active patterns protruding from a surface of a substrate;
an insulating interlayer covering sidewalls and upper surfaces of the active patterns, wherein the insulating interlayer includes an opening extending in a direction crossing an extension direction of the active patterns;
a gate structure in a lower portion of the opening, the gate structure including a metal;
a capping structure on the gate structure, wherein the capping structure includes a capping layer and at least one surface treatment layer stacked on each other; and
a dielectric residue protruding from an upper surface of the gate structure and extending into the capping structure, wherein the dielectric residue includes a metal included in the gate structure.

18. The semiconductor device of claim 17, wherein the dielectric residue includes a metal oxide, a metal nitride or a metal oxynitride.

19. The semiconductor device of claim 17, wherein the capping layer includes silicon nitride, and the at least one surface treatment layer includes silicon oxynitride.

20. The semiconductor device of claim 17, further comprising:
an insulating interlayer covering the capping structure; and
an upper pattern having conductivity on the insulating interlayer.
